(19) United States
(12) Patent Application Publication
(10) Pub. No.: US 2011/0042728 A1
(43) Pub. Date: Feb. 24, 2011

(54) SEMICONDUCTOR DEVICE WITH ENHANCED STRESS BY GATES STRESS LINER

(75) Inventors: Kangguo Cheng, Albany, NY (US); Bruce B. Doris, Yorktown Heights, NY (US); Charles William Koburger, III, Albany, NY (US)

Correspondence Address: SCULLY, SCOTT, MURPHY & PRESSER, P.C., 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 12/542,748

(22) Filed: Aug. 18, 2009

(51) Int. Cl. H01L 29/78; H01L 21/31; H01L 21/318; H01L 21/306; H01L 21/3205; H01L 21/8238

(52) U.S. Cl. 257/288; 438/761; 438/763; 438/703; 438/584; 438/595; 257/E21.24; 257/E21.293; 257/E21.215; 257/E21.295; 257/E21.632; 257/E29.255

(57) ABSTRACT

In one embodiment, a method is provided for forming stress in a semiconductor device. The semiconductor device may include a gate structure on a substrate, wherein the gate structure includes at least one dummy material that is present on a gate conductor. A conformal dielectric layer is formed atop the semiconductor device, and an interlevel dielectric layer is formed on the conformal dielectric layer. The interlevel dielectric layer may be planarized to expose at least a portion of the conformal dielectric layer that is atop the gate structure, in which the exposed portion of the conformal dielectric layer may be removed to expose an upper surface of the gate structure. The upper surface of the gate structure may be removed to expose the gate conductor. A stress inducing material may then be formed atop the at least one gate conductor.

### BACKGROUND

The present disclosure relates to semiconductor devices and methods of forming semiconductor devices including stressed materials. For more than three decades, the continued miniaturization of silicon metal oxide semiconductor field effect transistors (MOSFETs) has driven the worldwide semiconductor industry. Various showstoppers to continued scaling have been predicated for decades, but a history of innovation has sustained Moore's Law in spite of many challenges. However, there are growing signs today that metal oxide semiconductor transistors are beginning to reach their traditional scaling limits. Since it has become increasingly difficult to improve MOSFETs and therefore complementary metal oxide semiconductor (CMOS) performance through continued scaling, methods for improving performance without scaling have become critical.

### SUMMARY

In one embodiment, a method of providing a semiconductor device is provided, in which a stress inducing material that is present atop a gate conductor of a gate structure induces a stress in a channel of a semiconductor device. In one example, a semiconductor structure including a gate structure is formed on a substrate, in which the gate structure includes at least one dummy material that is present on at least one gate conductor, wherein the at least one gate conductor is present on a gate dielectric. A conformal dielectric layer can be formed overlying the semiconductor structure. An interlevel dielectric layer may be formed on the conformal dielectric layer, in which the interlevel dielectric layer is planarized to expose at least a portion of the conformal dielectric layer that is overlying the gate structure. The exposed portion of the conformal dielectric layer is removed to expose an upper surface of the gate structure. The dummy material may be removed from the gate structure to expose the at least one gate conductor. A stress inducing material can be formed on the at least one gate conductor.

In another embodiment, a method of forming a CMOS device is provided, in which a stress inducing material that is present atop the gate conductor of the gate structures to the CMOS devices induces a stress in the channel of the semiconductor device. In one example, the

method of fabricating a CMOS device includes providing a substrate having a first device region and a second device region. A first conductivity type semiconductor device may be formed in the first device region of the substrate, in which the first conductivity type semiconductor device includes a first gate structure including at least one first dummy material that is present on at least one first gate conductor. A second conductivity type semiconductor device may be formed in the second device region of the substrate, in which the second conductivity type semiconductor device includes a second gate structure including at least one second dummy material that is present on at least one second gate conductor. At least one dielectric layer may be formed over the first conductivity type semiconductor device and the second conductivity type semiconductor device. A portion of the at least one dielectric layer may be removed to expose the first dummy material of the first conductivity type semiconductor device, wherein a remaining portion of the at least one dielectric layer is present over the second conductivity type semiconductor device. The first dummy material is removed, and a first stress inducing material is formed on an upper surface of the at least one first gate conductor. The remaining portion of the at least one dielectric layer may be removed. The second dummy material may be removed, and a second stress inducing material may be formed on an upper surface of the second gate conductor.

### DESCRIPTION OF THE DRAWINGS

The following detailed description, given by way of example and not intended to limit the invention solely thereto, will best be appreciated in conjunction with the accompanying drawings, wherein like reference numerals denote like elements and parts, in which:

FIG. 1 is a side cross-sectional view of a substrate having a first conductivity type semiconductor device present in a first device region and a second conductivity type semiconductor device present in a second device region, wherein each of the first conductivity type semiconductor devices includes a gate structure having a dummy material present therein, as used in a method for forming a semiconductor device, in accordance with one embodiment of the present invention.

FIG. 2A is a side cross-sectional view depicting forming at least one dielectric layer over the first conductivity type semiconductor device and the second conductivity type semiconductor device, in which the at least one dielectric layer includes a tensile stress inducing liner atop the first conductivity type semiconductor device and a compressive stress inducing liner atop the second conductivity type semiconductor device, in accordance with one embodiment of the present invention.

FIG. 2B is a side cross-sectional view depicting forming at least one dielectric layer over the first conductivity type semiconductor device and the second conductivity type semiconductor device, in which the at least one dielectric layer includes a conformal dielectric layer in a substantially neutral stress state, in accordance with one embodiment of the present invention.

FIG. 3A is a side cross-sectional view depicting removing a portion of the tensile stress inducing liner to expose the first dummy material of the first conductivity type semiconductor device, in which the compressive stress inducing liner is present over the second conductivity type semiconductor device, in accordance with one embodiment of the present invention.

FIG. 3B is a side cross-sectional view depicting removing a first portion of the conformal dielectric layer to expose the first dummy material of the first conductivity type semiconductor device, in which a second portion of the conformal dielectric layer is present over at least the second conductivity type semiconductor device, in accordance with one embodiment of the present invention.

FIG. 4A is a side cross-sectional view depicting one embodiment of forming a first stress inducing material on the at least one first gate conductor of the structure depicted in FIG. 3A.

FIG. 4B is a side cross-sectional view depicting one embodiment of forming a first stress inducing material on the at least one first gate conductor of the structure depicted in FIG. 3B.

FIG. 5A is a side cross-sectional view depicting removing a portion of the compressive stress inducing liner to expose the second dummy material of the second conductivity type semiconductor device, removing the second dummy material, and forming a second drain inducing material on the second gate conductor, in accordance with one embodiment of the present invention.

FIG. 5B is a side cross-sectional view depicting removing of the second portion of the conformal dielectric layer, removing the second dummy material, and forming a second drain inducing material on the second gate conductor, in accordance with one embodiment of the present invention.

FIGS. 6A and 6B are side cross-sectional views of a method for forming a stress inducing material atop the gate structure of a metal oxide semiconductor field effect transistor (MOSFET), in accordance with some embodiments of the present invention.

### DETAILED DESCRIPTION

Detailed embodiments of the present invention are disclosed herein; however, it is to be understood that the disclosed embodiments are merely illustrative of the invention that may be embodied in various forms. In addition, each of the examples given in connection with the various embodiments of the invention are intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the present invention.

The embodiments of the present invention relate to methods for producing semiconductor devices having stress induced performance enhancements. In one embodiment, a method is provided, in which a stress inducing material is positioned atop the gate conductor of a gate structure to a semiconductor device, e.g., field effect transistor (FET), to induce a stress in the channel of a semiconductor device. When describing the inventive method and structures, the following terms have the following meanings, unless otherwise indicated.

As used herein, “semiconductor device” refers to an intrinsic semiconductor material that has been doped, that is, into which a doping agent has been introduced, giving it different electrical properties than the intrinsic semiconductor. Doping involves adding dopant atoms to an intrinsic semiconductor, which changes the electron and hole carrier concentrations of the intrinsic semiconductor at thermal equilibrium. Dominant carrier concentration in an extrinsic semiconductor determines the conductivity type of the semiconductor.

As used herein, the term “conductivity type” denotes a dopant region being p-type or n-type.

As used herein, “p-type” refers to the addition of impurities to an intrinsic semiconductor that creates deficiencies of valence electrons. In a silicon containing substrate, examples of n-type dopants, i.e., impurities include but are not limited to boron, aluminum, gallium and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

A “gate structure” means a structure used to control output current (i.e., flow of carriers in the channel) of a semiconducting device through electrical or magnetic fields.

As used herein, the term “channel” is the region underlying the gate structure and between the source and drain of a semiconductor device that becomes conductive when the semiconductor device is turned on.

As used herein, the term “drain” means a doped region in semiconductor device located at the end of the channel, in which carriers are flowing out of the transistor through the drain.

As used herein, the term “source” is a doped region in the semiconductor device, in which majority carriers are flowing into the channel.

The term “stress inducing liner” and “stress inducing material” denotes a material having an intrinsic stress, in which the intrinsic stress effectuates a stress in an underlying material.

The term “compressive stress inducing material” denotes a material having an intrinsic compressive stress, in which the intrinsic compressive stress produces a compressive stress in an underlying material.

The term “tensile stress inducing material” denotes a material layer having an intrinsic tensile stress, in which the intrinsic tensile stress produces a tensile stress in an underlying material.

“Epitaxial growth and/or deposition” means the growth of a semiconductor material on a deposition surface of a semiconductor material, in which the semiconductor material being grown has the same crystalline characteristics as the semiconductor material of the deposition surface.

The term “Si:C” or “carbon-doped silicon” as used herein refers to silicon having substitutional carbon atoms located therein. The substitutional carbon atoms and the silicon atoms form a silicon-carbon alloy, which is a semiconductor material.

As used herein, the terms “insulating” and “dielectric” denote a material having a room temperature conductivity of less than 10⁻¹⁰ (Ω-m)⁻¹.

A “high-k” dielectric is a dielectric or insulating material having a dielectric constant that is greater than the dielectric constant of silicon oxide.

The term “direct contact” means that a first element, such as a first structure, and a second element, such as a second structure, are connected without any intermediary conducting, insulating or semiconductor layers at the interface of the two elements.

“Planarization” is a material removal process that employs at least mechanical forces, such as frictional media, to produce a planar surface.

“Chemical Mechanical Planarization” is a material removal process using both chemical reactions and mechanical forces to remove material and planarize a surface.

As used herein, the term “selective” in reference to a material removal process denotes that the rate of material removal for a first material is greater than the rate of removal for at least another material of the structure to which the material removal process is being applied.

The terms “overlying”, “atop”, “positioned on” or “positioned atop” means that a first element, such as a first structure, is present on a second element, such as a second structure, wherein intervening elements, such as an interface structure, e.g. interface layer, may be present between the first element and the second element.

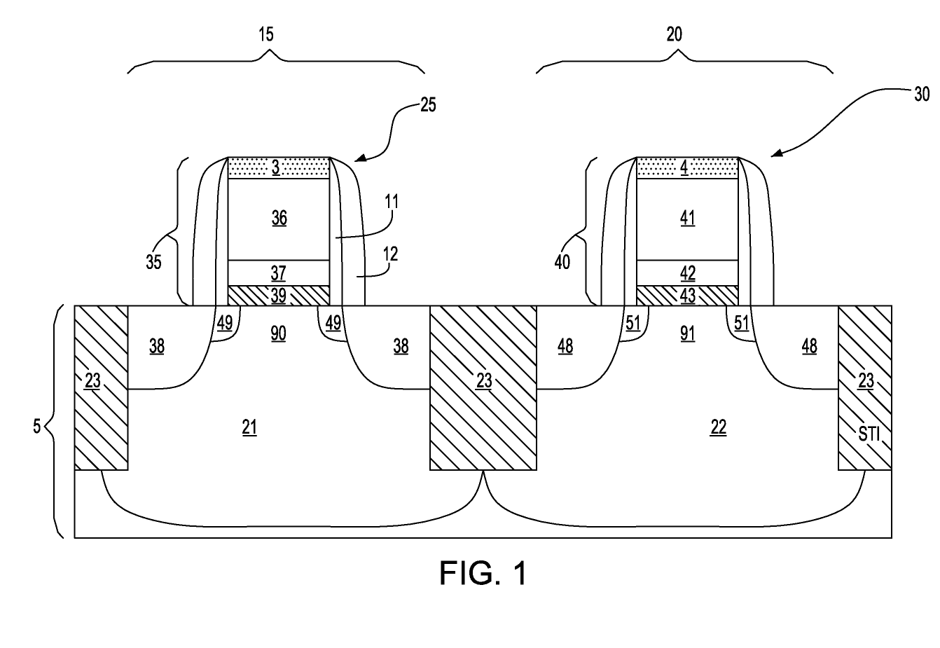

FIGS. 1-5 depict one embodiment of a method for applying a stress to the channel of a semiconductor device, which results in a performance enhancement of the device, e.g., increased charge carrier speed. It has been discovered that as the dimensions of semiconductor devices shrink with increased scaling, the space between devices is also decreasing, and the transfer of stress from the stress inducing materials that are adjacent to the gate structure is becoming less efficient. In one embodiment, the method disclosed herein increases the efficiency of stress transfer to the semiconductor devices by employing replacement gate technology to position stress inducing materials directly atop the surface of the gate conductor.

FIG. 1 depicts one embodiment of a substrate 5 having a first conductivity type semiconductor device 25 present in a first device region 15 and a second conductivity type semiconductor device 30 present in a second device region 20, wherein each of the first and second conductivity type semiconductor devices 25, 30 includes a gate structure 35, 40 having a dummy material 36, 41 present on at least one gate conductor 37, 42.

The substrate 5 may be composed of a Si-containing material. The term “Si-containing” is used herein to denote a material that includes silicon. Illustrative examples of Si-containing materials include, but are not limited to: Si, SiGe, SiGeC, SiC, polysilicon, i.e., polySi, epitaxial silicon, i.e., epi-Si, amorphous Si, i.e., α:Si, and multi-layers thereof. Although silicon is the predominantly used semiconductor material in wafer fabrication, alternative semiconductor materials can be employed, such as, but not limited to, germanium, gallium arsenide, gallium nitride, silicon germanium, cadmium telluride and zinc sellenide. Although the substrate 5 is depicted as a bulk-Si substrate, semiconductor on insulator (SOI) substrates have also been contemplated and are within the scope of the present disclosure.

A plurality of well regions 21, 22 may be located within the substrate 5 and separated by a plurality of isolation regions 23. In one embodiment, the well regions 21, 22 correspond to the first and second device regions 15, 20, in which the isolation region 23 is present between the first device region 15 and the second device region 20. In one example, in which the first device region 15 is processed to provide at least one n-type field effect transistor (nFET), a first well region 21 is present in the first device region 15 being doped to a p-type conductivity. In one example, in which the second device region 20 is processed to provide at least one p-type field effect transistor (pFET), a second well region 22 is present in the second device region 20 being doped to an n-type conductivity.

The isolation regions 23 may comprise any of several dielectric isolation materials. Non-limiting examples include oxides, nitrides and oxynitrides, particularly of silicon, but oxides, nitrides and oxynitrides of other elements are not excluded. In one embodiment, the isolation regions 23 primarily comprise an oxide of silicon.

Still referring to FIG. 1, in one embodiment, at least one first conductivity type semiconductor device 25, i.e., nFET, is formed within and upon the first well region 21 in the first device region 15 of the substrate 5, and at least one second conductivity type semiconductor device 30, i.e., pFET, is formed within and upon the second well region 22 of the second device region 20 of the substrate 5.

In one embodiment, the first conductivity type semiconductor device 25 includes a first gate structure 35, first source and drain regions 38 adjacent to the first gate structure 35, in which the first gate structure 35 further includes a first gate dielectric 39 underlying at least one first gate conductor 37. A first dummy material 36 may be present on the first gate dielectric 39. In one embodiment, the second conductivity type semiconductor device 30 includes a second gate structure 40, second source and drain regions 48 adjacent to the second gate structure 40, in which the second gate structure 40 further includes a second gate dielectric 43 underlying at least one second gate conductor 42. A second dummy material 41 may be present on the second gate dielectric 43.

The first and second gate dielectrics 39, 43 may individually comprise separate dielectric materials such as oxides, nitrides and oxynitrides of silicon that have a dielectric constant ranging from 3.9 to 10, as measured in a vacuum at room temperature. Alternatively, one or both of the first and second gate dielectric 39, 43 may be composed of a higher dielectric constant dielectric material having a dielectric constant ranging from 10 to 100. Such higher dielectric constant dielectric materials may include, but are not limited to, hafnium oxides, hafnium silicates, titanium oxides, barium-strontium-titantates (BSTs) and lead-zirconate-titanates (PZTs). The first and second gate dielectrics 39, 43 may be formed using any of several deposition and growth methods, including but not limited to, thermal or plasma oxidation or nitridation methods, chemical vapor deposition methods and physical vapor deposition methods. The first and second gate dielectrics 39, 43 may be composed of the same material or different materials. Although the first and second gate dielectrics 39, 43 are depicted in the supplied figures as each being a single layer, embodiments have been contemplated in which the first and second gate dielectrics 39, 43 are each a multi-layered structure of conductive materials. In one embodiment, the first and second gate dielectrics 39, 43 have a thickness ranging from 10 angstroms to 200 angstroms.

The first and second gate conductors 37, 42 may be composed of conductive materials including, but not limited to metals, metal alloys, metal nitrides and metal silicides, as well as laminates thereof and composites thereof. In one embodiment, the first and second gate conductors 37, 42 may be any conductive metal including, but not limited to W, Ni, Ti, Mo, Ta, Cu, Pt, Ag, Au, Ru, Ir, Rh, and Re, and alloys that include at least one of the aforementioned conductive elemental metals. The first and second gate conductors 37, 42 may also comprise doped polysilicon and/or polysilicon-germanium alloy materials (i.e., having a dopant concentration from about 1e18 to about 1e22 dopant atoms per cubic centimeter) and polycide materials (doped polysilicon/metal silicide stack materials). The first and second gate conductors 37, 42 may be composed of the same material or different materials. The first and second gate conductors 37, 42 may be formed using a deposition method including, but not limited to, salicide methods, atomic layer deposition methods, chemical vapor deposition methods and physical vapor deposition methods, such as, but not limited to evaporative methods and sputtering methods. Although the first and second gate conductors 37, 42 are depicted in the supplied figures as each being a single layer, embodiments have been contemplated in which the first and second gate conductors 37, 42 are each a multi-layered structure of conductive materials.

The first and second dummy material 36, 41 may be composed of any material that can be etched selectively to the underlying first and second gate conductors 37, 42. In one embodiment, the first and second dummy material 36, 41 may be composed of a silicon-containing material, such as polysilicon. Although, the first and second dummy material 36, 41 is typically composed of a semiconductor material, the first and second dummy material 36, 41 may also be composed of a dielectric material, such as an oxide, nitride or oxynitride material, or amorphous carbon. The first and second dummy material 36, 41 may be formed using a deposition process such as chemical vapor deposition. Variations of CVD processes include, but not limited to, Atmospheric Pressure CVD (APCVD), Low Pressure CVD (LPCVD) and Plasma Enhanced CVD (EPCVD), Metal-Organic CVD (MOCVD) and combinations thereof may also be employed. A first and second dielectric cap 3, 4 may be present on the first and second dummy material 36, 41. In one embodiment, the first and second dielectric cap 3, 4 are each composed of a dielectric material, such as an oxide, nitride or oxynitride material. In one example, the first and second dielectric cap 3, 4 are each composed of silicon nitride. In some embodiments, the first and second dielectric cap 3, 4 may be omitted from the first and second gate structures 25, 30.

The first and second gate structures 35, 40 may further comprise sidewalls spacers. In one embodiment, each of the first and second gate structures 35, 40 includes a first sidewall spacer 11 and a second sidewall spacer 12. The first and second sidewall spacers 11, 12 may be composed of materials including, but not limited to, conductive materials and dielectric materials. The spacer materials may be formed using methods that are generally conventional in the semiconductor fabrication art. Included in general are methods that are analogous, equivalent, or identical to the methods that are used for forming the isolation regions 23. The first sidewall spacer 11 and a second sidewall spacer 12 are often formed by using a blanket layer deposition and anisotropic etchback method. In one embodiment, the first sidewall spacer 11 is composed of silicon oxide and has a thickness ranging from 10 angstroms to 100 angstroms, and the second sidewall spacer 12 is composed of silicon nitride material and has a thickness ranging from 50 to 1000 angstroms. In one embodiment, the first and second gate structures 35, 40 may comprise only sidewalls spacer 12.

In one embodiment, the first conductivity type semiconductor device 25 includes first source and drain regions 38 doped with a first conductivity dopant adjacent to the first gate structure 35, and the second conductivity type semiconductor device 30 includes second source and drain regions 48 with a second conductivity dopant adjacent to the second gate structure 40. In one embodiment, the first source and drain regions 38 are implanted with an n-type dopant, in which the first conductivity type semiconductor device 25 is an n-type conductivity field effect transistor (nFET). In one embodiment, n-type FET devices are produced by doping the silicon-containing substrate 5 with elements from group V of the Periodic Table of Elements. In one embodiment, the group V element is phosphorus, antimony or arsenic. In one embodiment, the second source and drain regions 48 are implanted with a p-type dopant, in which the second conductivity type semiconductor device 30 is a p-type conductivity field effect transistor (nFET). P-type FET devices are produced by doping the silicon containing substrate 5 with elements from group III of the Periodic Table of Elements. In one embodiment, the group III element is boron, aluminum, gallium or indium.

The first and second source and drain regions 38, 48 may be doped using ion implantation. Resulting dopant concentrations for the first and second source and drain regions 38, 48 may range from 1×10¹⁸ dopant atoms per cubic centimeter to 1×10²¹ dopant atoms per cubic centimeter. The first and second conductivity type semiconductor devices 25, 30 may further include extension regions 49, 51 and/or halo implant regions. The implants to provide the extension regions 49, 51 and the halo implant regions may include a combination of normally incident and angled implants to form the desired grading and implant depth.

Still referring to FIG. 1, in some embodiments of the invention, stress inducing wells (not shown) may be present within first and second source and drain regions 38, 48. In one embodiment, tensile stress inducing wells are positioned adjacent to the first device channel 90 in the first source and drain regions 38 (not shown). The tensile stress inducing well may include silicon doped with carbon (Si:C) or silicon germanium doped with carbon (SiGe:C). The tensile stress inducing wells comprising intrinsically tensile Si:C can be epitaxially grown atop a recessed portion of the substrate 5. The term “intrinsically tensile Si:C layer” denotes that a Si:C layer is under an internal tensile stress, in which the tensile stress is produced by a lattice mismatch between the smaller lattice dimension of the Si:C and the larger lattice dimension of the layer on which the Si:C is epitaxially grown. The tensile stress inducing wells produce a tensile stress within the first device channel 90. The carbon (C) content of the epitaxial grown Si:C ranges from 0.3% to 10%, by atomic weight %. In another embodiment, the carbon (C) content of the epitaxial grown Si:C may range from 1% to 2%.

In one embodiment, compressive stress inducing wells (not shown) are positioned adjacent the second device channel 91 in the second source and drain regions 48. Compressive stress inducing wells formed of intrinsically compressive SiGe can be epitaxially grown atop a recessed portion of the substrate 5. The term “intrinsically compressive SiGe layer” denotes that a SiGe layer is under an intrinsic compressive stress (also referred to as an intrinsic compressive stress), in which the compressive stress is produced by a lattice mismatch between the larger lattice dimension of the SiGe and the smaller lattice dimension of the layer on which the SiGe is epitaxially grown. The compressive stress inducing wells produce a compressive stress in the second device channel 91. The Ge content of the epitaxial grown SiGe may range from 5% to 60%, by atomic weight %. In another embodiment, the Ge content of the epitaxial grown SiGe may range from 10% to 40%.

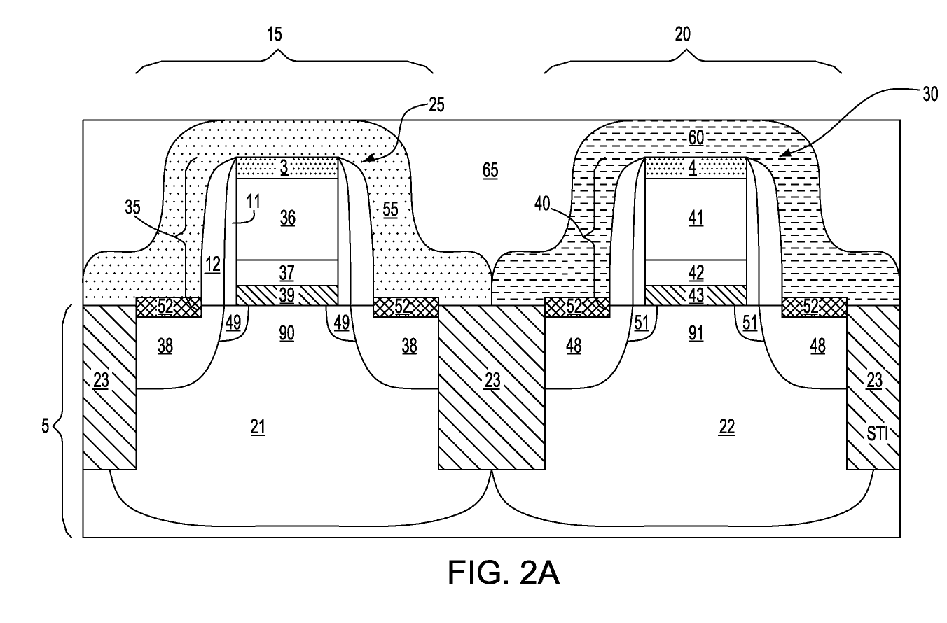

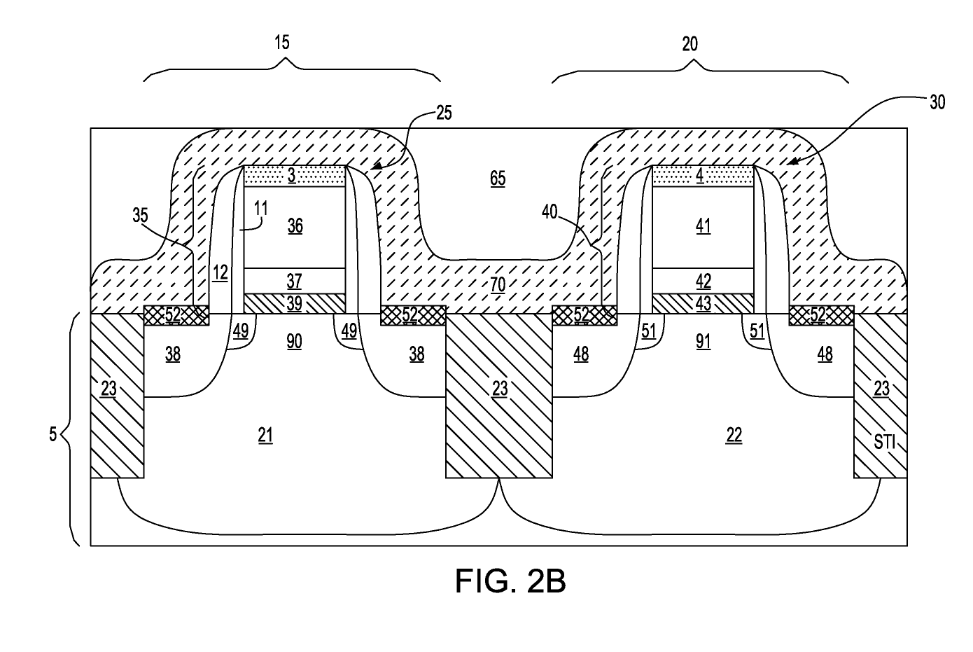

FIG. 2A depicts one embodiment of forming at least one dielectric layer over the first conductivity type semiconductor device 25 and the second conductivity type semiconductor device 30, in which the at least one dielectric layer includes a tensile stress inducing liner 55 atop the first conductivity type semiconductor device 25, i.e., NET, and a compressive stress inducing liner 60 atop the second conductivity type semiconductor device 30, i.e., pFET. The tensile stress inducing liner 55 and the compressive stress inducing liner 60 may be formed using deposition, photolithography and etching. More specifically, in one embodiment, the tensile stress inducing liner 55 and the compressive stress inducing liner 60 are blanket deposited over the first device region 15 and the second device region 25, wherein photolithopraphy and etching dictate which of the first and second device regions 15, 20, in which the remaining portions of the tensile stress inducing liner 55 and the compressive stress inducing liner 60 are positioned. In one embodiment, the tensile stress inducing liner 55 and the compressive stress inducing liner 60 are deposited using a conformal deposition process to provide a conformal layer. As used herein, “a conformal layer” is a deposited material having a thickness that remains the same regardless of the geometry of underlying features on which the layer is deposited. A conformal insulating layer is a conformal layer composed of an insulating material.

Plasma enhanced chemical vapor deposition (PECVD) can form stress inducing dielectrics having a compressive or tensile internal stress. The stress state of the stressed dielectric layer deposited by PECVD can be controlled by changing the deposition conditions to alter the reaction rate within the deposition chamber. More specifically, the stress state of the deposited stressed dielectric layer may be set by changing the deposition conditions such as: SiH₄/N₂/He gas flow rate, pressure, RF power, and electrode gap.

Rapid thermal chemical vapor deposition (RTCVD) can provide stress inducing dielectrics having an internal tensile stress. The magnitude of the internal tensile stress produced within the stressed dielectric layer deposited by RTCVD can be controlled by changing the deposition conditions. More specifically, the magnitude of the tensile stress within the deposited stressed dielectric layer may be set by changing deposition conditions such as: precursor composition, precursor flow rate and temperature.

In one embodiment, tensile stress inducing liner 55 formation includes PECVD of silicon nitride, in which the deposition conditions include a low frequency power ranging from 0 W to 100 W, a high frequency power ranging from 200 W to 600 W, a silane flow rate ranging from 50 sccm to 200 seem, an NH₃ flow rate ranging from 1,500 sccm to 3,000 sccm, and a deposition pressure of 15 Torr or less. The tensile stress inducing liner 55 can be deposited to a thickness generally in the range from 300 angstroms to 1500 angstroms. In one embodiment, the tensile stress liner 55 has a thickness ranging from 300 angstroms to 1000 angstroms.

Optionally, silicide 52 may be formed by conventional salicide process on source/drain regions 38 and 48 before the deposition of the stress inducing liners 55 and 60.

In one embodiment, the compressive stress inducing liner 60 comprises PECVD of silicon nitride, in which the deposition conditions include a low frequency power ranging from 500 W to 1,500 W, a high frequency power ranging from 250 W to 500 W, a silane flow rate ranging from 800 sccm to 2,000 sccm, an NH₃ flow rate ranging from 6,000 to 10,000 sccm, and a deposition pressure of 10 Torr or less. The compressive stress inducing liner 60 can be deposited to a thickness generally in the range of from 300 angstroms to 1500 angstroms. In one embodiment, compressive stress inducing liner 60 has a thickness ranging from 300 angstroms to 1000 angstroms.

FIG. 2B depicts another embodiment of the invention, in which forming the at least one dielectric layer over the first conductivity type semiconductor device 25 and the second conductivity type semiconductor device 30 includes a conformal dielectric layer 70 that is in a in substantially neutral stress state. By substantially neutral state it is meant that the intrinsic stress of the conformal dielectric layer is no greater than 100 MPa (mega Pascals). The conformal dielectric layer 70 may be composed of any dielectric layer including, but not limited to oxides, nitrides, oxynitrides or combinations and multi-layers thereof. In one embodiment, the conformal dielectric layer 70 is composed of silicon oxide. In one embodiment, the conformal dielectric layer 70 is composed of silicon nitride. The conformal dielectric layer 70 may be formed by a deposition method including, but not limited to spinning from solution, spraying from solution, chemical vapor deposition (CVD), plasma enhanced CVD (PECVD), plasma oxidation, plasma nitridation, sputter deposition, reactive sputter deposition, ion-beam deposition, and evaporation. The conformal dielectric layer 70 can be deposited to a thickness generally in the range from 300 angstroms to 1500 angstroms. In another embodiment, the conformal dielectric layer 70 is deposited to a thickness ranging from 300 angstroms to 1500 angstroms.

Referring to FIGS. 2A and 2B, in some embodiments, following the formation of the tensile stress inducing liner 55 and the compressive stress inducing liner 60, as depicted in FIG. 2A, or following the formation of the conformal dielectric layer 70, as depicted in FIG. 2B, an interlevel dielectric layer 65 is non-conformally formed overlying the first device region 15 and the second device region 20.

The interlevel dielectric layer 65 may be selected from the group consisting of silicon-containing materials such as silicon oxide, silicon nitride, SiOₓN_{y}, SiC, SiCO, SiCOH, and SiCH compounds; the above-mentioned silicon-containing materials with some or all of the Si replaced by Ge; carbon-doped oxides; inorganic oxides; inorganic polymers; hybrid polymers; organic polymers such as polyamides or SiLK™; other carbon-containing materials; organo-inorganic materials such as spin-on glasses and silsesquioxane-based materials; and diamond-like carbon (DLC, also known as amorphous hydrogenated carbon, α-C:H). Additional choices for the interlevel dielectric layer 65 include any of the aforementioned materials in porous form, or in a form that changes during processing to or from being porous and/or permeable to being non-porous and/or non-permeable.

The interlevel dielectric layer 65 may be formed by various deposition methods, including, but not limited to: spinning from solution, spraying from solution, chemical vapor deposition (CVD), plasma enhanced CVD (PECVD), sputter deposition, reactive sputter deposition, ion-beam deposition, and evaporation. The interlevel dielectric layer 65 may be planarized to expose the portion of the tensile stress inducing liner 55 and the portion of the compressive stress inducing liner 60 that is present atop the first and second gate structures 25, 30, as depicted in FIG. 2A, or to expose the portion of the conformal dielectric layer 70 that is present atop the first and second gate structures 25, 30, as depicted in FIG. 2B. In one embodiment, the planarization process includes chemical mechanical polishing (CMP) or grinding. Chemical mechanical planarization (CMP) is a material removal process using both chemical reactions and mechanical forces to remove material and planarize a surface.

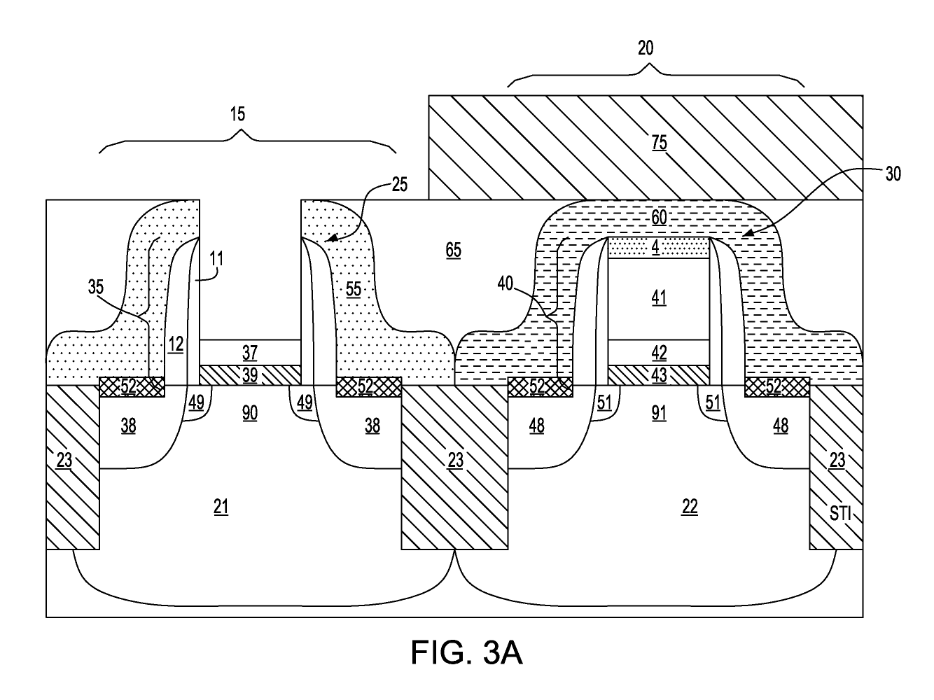

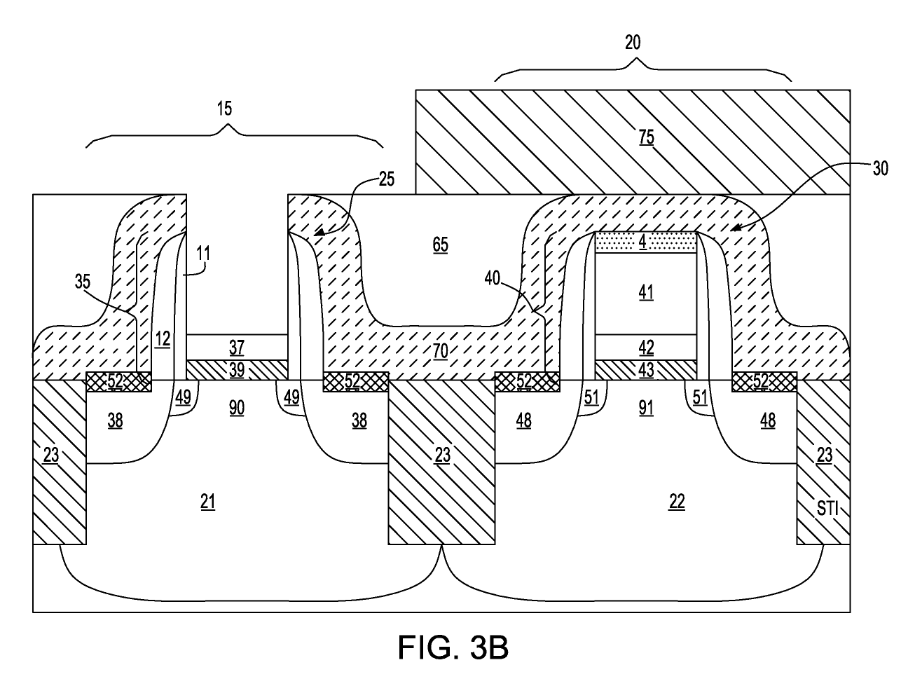

FIG. 3A depicts one embodiment of removing a portion of the at least one dielectric layer, i.e., the tensile stress inducing liner 55, to expose the first dummy material 36 of the first conductivity type semiconductor device 25, in which a remaining portion of the at least one dielectric layer, i.e., the compressive stress inducing liner 60, is present over the second conductivity type semiconductor device 30. In the embodiments, in which the at least one dielectric layer is provided by a conformal dielectric layer 70 having the neutral stress state, a first portion of the conformal dielectric layer 70 is removed from atop the first gate structure 35, wherein a second portion of the conformal dielectric layer 70 remains overlying the second device region 20, as depicted in FIG. 3B.

Referring to FIGS. 3A and 3B, in one embodiment, a photoresist mask 75 is formed overlying the second device region 20 of the substrate 5. The photoresist mask 75 is formed atop the second device region 20 by photolithography steps. More specifically, a layer of photoresist material may be deposited atop the entire structure. The photoresist material can be composed of dielectrics including carbon, oxygen, and various inorganic materials. The photoresist layer may then be selectively exposed to light and developed to pattern a block mask, protecting at least one region, e.g., second device region 20, of the substrate 5 and exposing at least another region, e.g., first device region 15, of the substrate 5. The exposed regions of the device are then processed while the regions underlying the photoresist mask 75 are protected. Specifically, in one embodiment, the at least one dielectric layer, i.e., the tensile stress inducing liner 55 or first portion of the conformal dielectric layer 70, is removed using an etching process with a selective etch chemistry, in which the etch chemistry removes the at least one dielectric layer selective to the photoresist mask 75.

Following removal of the at least one dielectric layer, i.e., tensile stress inducing liner 55 or first portion of the conformal dielectric layer 70, the upper portion of the first gate stack 35, i.e., the first dielectric cap 3 and the first dummy material 36, may be removed by etching with an etch chemistry that is selective to the first gate structure 37. More specifically, in one embodiment, a first etch chemistry removes the first dielectric cap 3 selective to the photoresist mask 75, the interlevel dielectric 65 and the first dummy material 36. In another embodiment, a second etch chemistry removes the first dummy material 36 selective to the photoresist mask 75, the interlevel dielectric 65 and the first gate conductor 37. In one embodiment, the etch chemistry is selected to remove the first dielectric cap 3 and the first dummy material 36 selective to the photoresist mask 75, the interlevel dielectric 65 and the first gate conductor 37. The photoresist mask 75 may then be removed by a chemical stripping process. The photoresist mask 75 may also be removed during the aforementioned etch processes to remove the first dummy material 36. In one embodiment, a hardmask (e.g., amorphous carbon which is not shown) can be used in conjunction with photoresist mask 75 to facilitate the removal of the first dummy material 36.

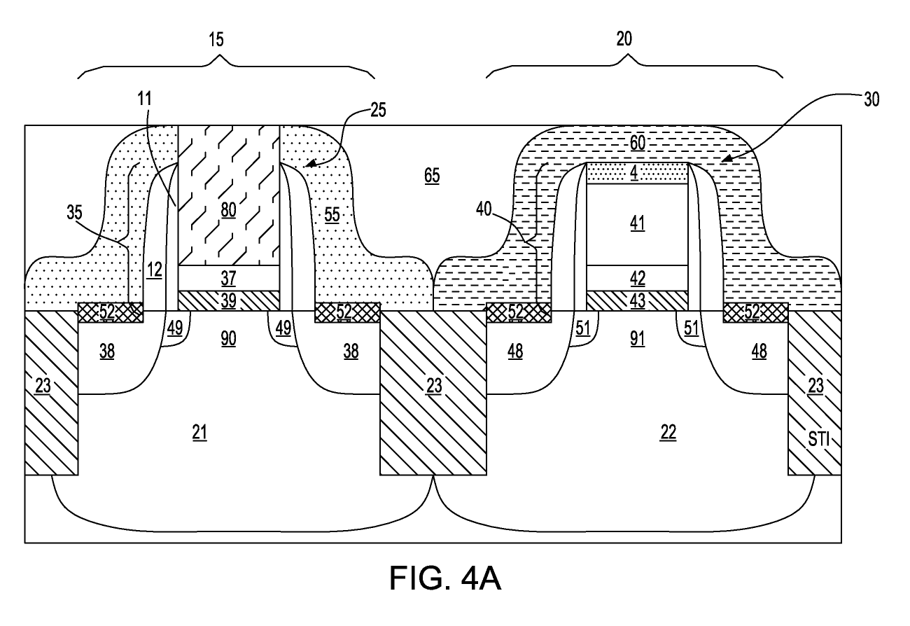

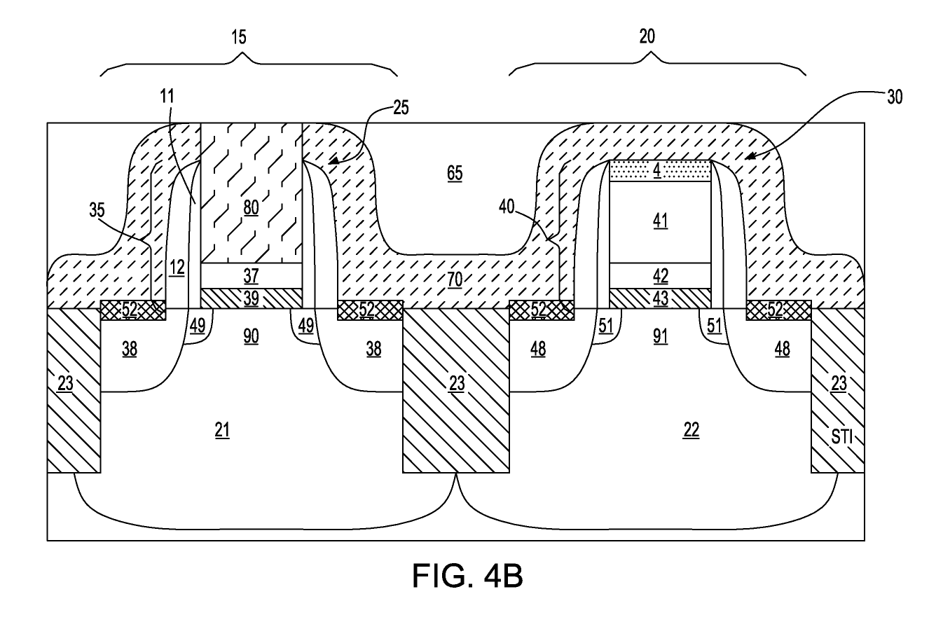

FIGS. 4A and 4B depict some embodiment of forming a first stress inducing material 80 on the at least one first gate conductor 37 of the first gate structure 35. In one embodiment, the first stress inducing material 80 may be composed of at least one of a stress inducing dielectric material or a stress inducing conductive material. In one example, the stress inducing conductive material comprises titanium (Ti), titanium nitride (TiN), tungsten (W), tungsten nitride (WN), tantalum (Ta), tantalum nitride (TaN), aluminum titanium nitride (AlTiN), and combinations thereof. The stress inducing conductive material may have either an intrinsic compressive stress or an intrinsic tensile stress, in which the stress state of the stress inducing conductive material may be determined by the deposition technique. In one embodiment, a stress inducing conductive material having an intrinsic tensile stress is provided depositing the conductive material using a chemical vapor deposition or atomic layer deposition process. Chemical vapor deposition (CVD) is a deposition process in which a deposited species is formed as a result of chemical reaction between gaseous reactants at greater than room temperature (25° C. to 900° C.); wherein solid product of the reaction is deposited on the surface on which a film, coating, or layer of the solid product is to be formed. Variations of CVD processes include but are not limited to Atmospheric Pressure CVD (APCVD), Low Pressure CVD (LPCVD) and Plasma Enhanced CVD (EPCVD), Metal-Organic CVD (MOCVD) and others. In one example, in which the first conductivity type semiconductor device 25 that is present in the first device region 15 is an n-type field effect transistor, the first stress inducing material 80 is a stress inducing conductive material composed of TiN that is deposited using chemical vapor deposition (CVD).

In another embodiment, the first stress inducing material 80 may be provided by a dielectric material having an intrinsic tensile stress. In one example, the first stress inducing material 80 may be composed of a similar material and formed using a similar process as the tensile stress inducing liner 55 that is described above with reference to FIG. 2A.

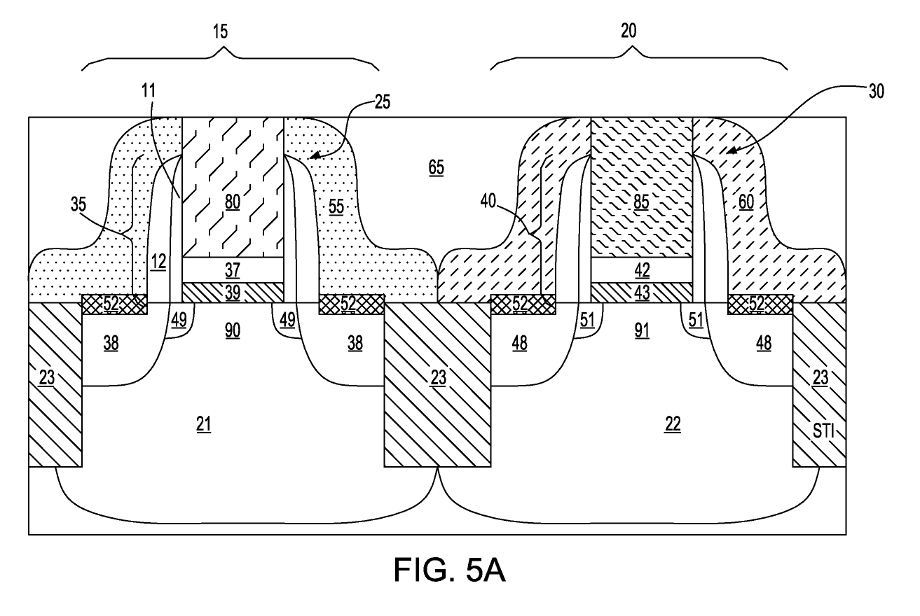

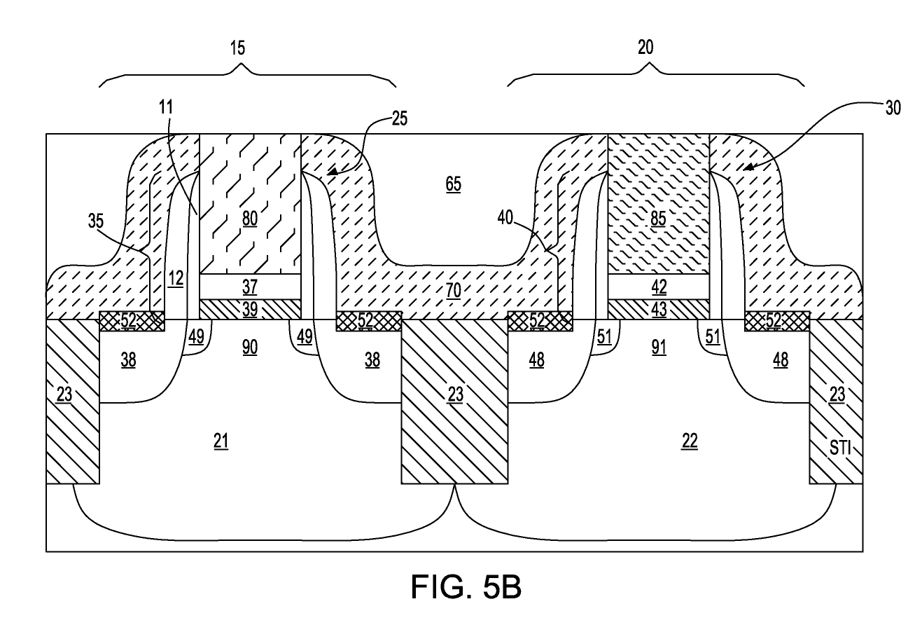

FIGS. 5A and 5B depict one embodiment of removing a portion of the at least one dielectric layer, i.e., the compressive stress inducing liner 60 or a second portion of the conformal dielectric layer 70, to expose the second dielectric cap 4 that is present on the second dummy material 41 of the second conductivity type semiconductor device 30. In the embodiments in which the second dielectric cap 4 is not present, removing the portion of the at least one dielectric layer from the upper surface of the second gate structure 40 exposes the second dummy material 41.

FIG. 5A depicts removing a portion of the compressive stress inducing liner 60 that is present atop the second gate structure 40 to expose the second dielectric cap 4 that is present on the second dummy material 41 of the second conductivity type semiconductor device 30, removing the dielectric cap 4 and the second dummy material 41, and forming a second drain inducing material 85 on the second gate conductor 42. In one embodiment, a first etch chemistry removes the second dielectric cap 4 selective to the first stress inducing material 80, the interlevel dielectric 65 and the second dummy material 41, in which a second etch chemistry removes the second dummy material 41 selective to the first stress inducing material 80, the interlevel dielectric 65 and the second gate conductor 42. In one embodiment, the etch chemistry is selected to remove the second dielectric cap 4 and the second dummy material 41 selective to the first stress inducing material 80, the interlevel dielectric 65 and the second gate conductor 42.

Still referring of FIG. 5A, a second stress inducing material 85 may then be formed on the second gate conductor 42 of the second gate structure 30. In one embodiment, the first stress inducing material 85 may be composed of at least one of a stress inducing dielectric material or a stress inducing conductive material. In one example, the stress inducing conductive material comprises titanium (Ti), titanium nitride (TiN), tungsten (W), tungsten nitride (WN), tantalum (Ta), aluminum titanium nitride (AlTiN), tantalum nitride (TaN), and combinations thereof. The stress inducing conductive material of the second stress inducing material 85 may have either an intrinsic compressive stress or intrinsic tensile stress, in which the stress state of the stress inducing conductive material may be determined by the deposition technique. In one embodiment, the stress inducing conductive material of the second stress inducing material 85 has an intrinsic compressive stress that is provided by depositing the conductive material using a physical vapor deposition (PVD), such as sputtering. As used herein, sputtering means a method of depositing a film of material on a semiconductor surface. A target of the desired material, i.e., source, is bombarded with particles, e.g., ions, which knock atoms from the target, and the dislodged target material deposits on the surface of the second gate conductor 42. Examples of sputtering techniques suitable for depositing a second stress inducing material 85 having an intrinsic compressive stress include, but are not limited too, DC diode sputtering (“also referred to as DC sputtering”), radio frequency (RF) sputtering, magnetron sputtering, and ionized metal plasma (IMP) sputtering. In one example, in which the second conductivity type semiconductor device 30 that is present in the second device region 20 is a p-type field effect transistor, the second stress inducing material 85 is a stress inducing conductive material having an intrinsic compressive stress composed of TiN that is deposited using sputter deposition.

In another embodiment, the second stress inducing material 85 may be provided by a dielectric material having an intrinsic compressive stress. In one example, the second stress inducing material 85 may be composed of a similar material and formed using a similar process as the compressive stress inducing liner 60 that is describe above with reference to FIG. 2A.

FIG. 5B depicts removing a second portion of the conformal dielectric layer 70, removing the second dummy material 41, and forming a second stress inducing material 85 on the second gate conductor 42. In one embodiment, prior to removing the second portion of the conformal dielectric layer 70, a photoresist mask may be formed overlying at least the first dummy material 80 that is present in the first device region 15 of the substrate 5, in which at least the second dummy material 41 that is present in the second device region 20 is exposed. In one embodiment, a first etch chemistry removes the second dielectric cap 4 selective to the photoresist mask, the interlevel dielectric 65 and the second dummy material 41, in which a second etch chemistry removes the second dummy material 41 selective to the photoresist mask, the interlevel dielectric 65 and the second gate conductor 42. In one embodiment, the etch chemistry is selected to remove the second dielectric cap 4 and the second dummy material 41 selective to the photoresist mask, the interlevel dielectric 65 and the second gate conductor 42. Following etching, the photoresist maybe removed using a chemical strip. A second stress inducing material 85 is then deposited atop the second gate conductor 42. The second stress inducing material 85 and method of forming is described above with reference to FIG. 5A.

Referring to FIGS. 5A and 5B, in one embodiment, the first conductivity type semiconductor device 25 includes a first stress inducing material 80 with an intrinsic tensile stress that produces a tensile stress within the first channel 90 that ranges from greater than 100 MPa (mega Pascals) to 2 GPa (giga Pascals), and the second conductivity type semiconductor device 30 includes a second stress inducing material 85 with an intrinsic compressive stress that produces a compressive stress within the second channel 91 that ranges from greater than 100 MPa to 2 GPa.

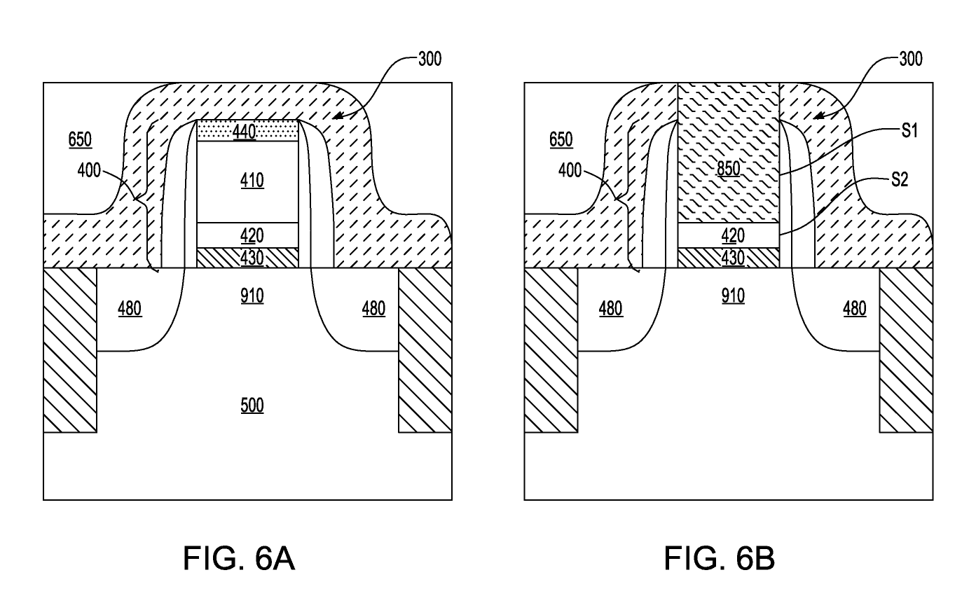

Although, the above description is directed to a CMOS device, the method is also applicable to a MOSFT devices. Referring to FIG. 6A, in one embodiment, a method of forming stress in a MOSFET is provided that may begin with providing a semiconductor device including a gate structure 400 on a substrate 500, in which the gate structure 400 includes at least one dummy material 410 that is present on at least one gate conductor 420. A conformal dielectric layer 300 is then formed atop the semiconductor device and an interlevel dielectric layer 650 is formed on the conformal dielectric layer 300. The interlevel dielectric layer 650 may be planarized to expose at least a portion of the conformal dielectric layer 300 that is atop the gate conductor 420. The exposed portion of the conformal dielectric layer 300 and the underlying dummy material 410 are then removed to expose an upper surface of the at least one gate structure 400. In one embodiment, a dielectric cap 440 is present atop the dummy material 410, which may also be removed after planarizing the interlevel dielectric layer 650. Referring to FIG. 6B, in one embodiment, a stress inducing material 850 is then formed atop the at least one gate conductor 420.

Referring to FIGS. 6A and 6B, in one embodiment, a semiconductor device is provided including a substrate 500 having source and drain regions 480 separated by a device channel 910, and a gate structure 400 present over the device channel 910. A gate dielectric 430 may be present between the gate conductor 420 and the device channel 910. A stress inducing material 850 may be present on an upper surface of the gate structure 400, wherein the sidewalls S1 of the stress inducing material 850 are aligned to the sidewalls S2 of the gate conductor 420. The alignment of the stress inducing material 850 to the gate conductor 420 results from the stress inducing material 850 being formed within the space previously occupied by the dummy material 410 of a replacement gate process, in which the dummy material 410 is either formed by the same etch mask that provides the gate conductor 420 or acts as an etch mask during formation of the gate conductor 420. It is noted that the conformal dielectric layer 300 may be substituted with a tensile stress liner or a compressive stress liner as discussed above in the embodiments of the invention consistent with FIGS. 1-5B. Further, the source and drain regions 480 depicted in FIGS. 6A and 6B may include the dopants and materials that are utilized in the source and drain regions 48 that are described above with reference to FIGS. 1-5B.

While this invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What is claimed is:

1. A method of forming stress in a semiconductor device comprising the steps of:
providing a semiconductor structure including a gate structure on a substrate, wherein the gate structure includes at least one dummy material that is present on at least one gate conductor;
forming a conformal dielectric layer atop the semiconductor structure;
forming an interlevel dielectric layer on the conformal dielectric layer;
planarizing the interlevel dielectric layer to expose at least a portion of the conformal dielectric layer that is atop the gate structure;
removing the portion of the conformal dielectric layer that is exposed and the dummy material to expose an upper surface of the at least one gate conductor; and
forming a stress inducing material atop the at least one gate conductor.

2. The method of claim 1, wherein the semiconductor structure comprises source and drain regions adjacent to the gate structure, in which the gate structure further comprises a gate dielectric underlying the at least one gate conductor.

3. The method of claim 2, wherein the dummy material comprises polysilicon, the at least one gate conductor comprises a metal gate, and the gate dielectric comprises a high-k dielectric material.

4. The method of claim 3, wherein the source and drain regions comprise an epitaxially grown stress inducing material.

5. The method of claim 4, wherein the epitaxially grown stress inducing material of the source and drain regions comprises a tensile stress or a compressive stress.

6. The method of claim 4, wherein the epitaxially grown stress inducing material comprise Si:C or SiGe and the substrate comprises Si.

7. The method of claim 6, wherein said conformal dielectric layer is a stress inducing liner having a compressive stress, wherein said forming said stress inducing liner comprises chemical vapor deposition of silicon nitride, wherein conditions of said chemical vapor deposition comprise a low frequency power ranging from 500 W to 1,500 W, a high frequency power ranging from 250 W to 500 W, a silane flow rate ranging from 800 sccm to 2,000 sccm, an NH₃ flow rate ranging from 6,000 sccm to 10,000 sccm, and a deposition pressure of 10 Torr or less.

8. The method of claim 6, wherein said conformal dielectric layer is a stress inducing liner has a tensile stress, wherein said forming said stress inducing liner comprises chemical vapor deposition of silicon nitride, wherein conditions of said chemical vapor deposition comprise a low frequency power ranging from 0 W to 100 W, a high frequency power ranging from 200 W to 600 W, a silane flow rate ranging from 50 sccm to 200 sccm, an NH₃ flow rate ranging from 1,500 sccm to 3,000 sccm, and a deposition pressure of 15 Torr or less.

9. The method of claim 1 wherein forming an interlevel dielectric layer on the conformal dielectric layer comprises depositing a dielectric selected from the group consisting of amorphous hydrogenated silicon (α-Si:H), silicon oxide, silicon nitride, SiOₓN_{y}, SiC, SiCO, SiCOH, SiCH, carbon-doped oxides, inorganic oxide, inorganic polymers; hybrid polymers, organic polymers, polyamides, organo-inorganic materials, spin-on glass, silsesquioxane-based materials, and diamond-like carbon (DLC).

10. The method of claim 1, wherein the removing of the conformal dielectric layer comprises planarization, and removing the dummy material to expose an upper surface of the at least one gate conductor comprises a selective etch process.

11. The method of claim 1, wherein the forming of the stress inducing material atop the at least one gate conductor comprises a tensile or compressive dielectric.

12. The method of claim 11, wherein said stress inducing material has a compressive stress, wherein said forming said stress inducing liner comprises chemical vapor deposition of silicon nitride, wherein conditions of said chemical vapor deposition comprise a low frequency power ranging from 500 W to 1,500 W, a high frequency power ranging from 250 W to 500 W, a silane flow rate ranging from 800 sccm to 2,000 sccm, an NH₃ flow rate ranging from 6,000 to 10,000 sccm, and a deposition pressure of 10 Torr or less.

13. The method of claim 11, wherein said stress inducing material has a tensile stress, wherein said forming said stress inducing liner comprises chemical vapor deposition of silicon nitride, wherein conditions of said chemical vapor deposition comprise a low frequency power ranging from 0 W to 100 W, a high frequency power ranging from 200 W to about 600 W, a silane flow rate ranging from 50 sccm to 200 sccm, an NH₃ flow rate ranging from 1,500 sccm to 3,000 sccm, and a deposition pressure of 15 Torr or less.

14. The method of claim 11, wherein the stress inducing material is a conductive material selected from the group consisting of Ti, TiN, W, WN, Ta and TaN.

15. A method of fabricating a CMOS device comprising:
providing a substrate having a first device region and a second device region;
forming a first conductivity type semiconductor device on the first device region of the substrate, wherein the first conductivity type semiconductor device includes a first gate structure including at least one first dummy material that is present on at least one first gate conductor;
forming a second conductivity type semiconductor device on a second device region of the substrate, wherein the second conductivity type semiconductor device includes at least one second dummy material that is present on at least one second gate conductor;
forming at least one dielectric layer over the first conductivity type semiconductor device and the second conductivity type semiconductor device;
removing a portion of the at least one dielectric layer to expose the first dummy material of the first conductivity type semiconductor device, wherein a remaining portion of the at least one dielectric layer is present over the second conductivity type semiconductor device;
removing the first dummy material;
forming a first stress inducing material on the at least one first gate conductor;
removing the remaining portion of the at least one dielectric layer;
removing the second dummy material; and
forming a second drain inducing material on the second gate conductor.

16. The method of claim 15 wherein the first conductivity type semiconductor device is an n-type field effect transistor (nFET) and the second conductivity type semiconductor device is a p-type field effect transistor (pFET).

17. The method of claim 16 wherein the first stress inducing material is present on an upper surface of the at least one first gate conductor, in which sidewalls of the first stress inducing material are aligned to sidewalls of the at least one first gate conductor, and the second stress inducing material is present on an upper surface of the at least one second gate conductor, in which sidewalls of the second stress inducing material are aligned to sidewalls of the at least one second gate conductor.

18. The method of claim 16, wherein the first stress inducing material is a tensile stress inducing material and the second stress inducing material is a compressive stress inducing material.

19. The method of claim 14, wherein forming at least one dielectric layer comprises:
depositing at least one conformal dielectric layer over the first device region and the second device region;
forming a interlevel dielectric layer over the conformal dielectric layer; and
planarizing the interlevel dielectric layer to expose the conformal dielectric layer that is present over the first dummy material and the second dummy material.

20. The method of claim 19, wherein the removing of the portion of the at least one dielectric layer to expose the first dummy material of the first conductivity type semiconductor device comprises:
forming a block mask protecting the remaining portion of the dielectric layer that is present over the second conductivity type semiconductor device; and
etching a portion of the at least one conformal dielectric layer that is present over the first dummy material selective to the block mask and the interlevel dielectric layer.

21. The method of claim 19, wherein the at least one conformal dielectric layer is in a substantially neutral stress state.

22. The method of claim 19, wherein the at least one conformal dielectric layer comprises a tensile stress inducing liner atop the first conductivity type semiconductor device and a compressive stress inducing liner atop the second conductivity type semiconductor device.

23. The method of claim 1, wherein the first stress inducing material atop the at least one first gate conductor comprises a tensile stress dielectric and the second stress inducing material atop the at least one second gate conductor comprises a compressive stress dielectric.

24. The method of claim 11, wherein the stress inducing material is a conductive material selected from the group consisting of Ti, TiN, W, WN, Ta and TaN.

25. A semiconductor device comprising:
a substrate having source and drain regions separated by a device channel; and
a gate structure present over the device channel; and
a stress inducing material present on the gate structure, wherein the sidewalls of the stress inducing material are aligned to the sidewalls of the gate structure.
